(19) United States
(12) Patent Application Publication
(10) Pub. No.: US 2016/0178666 A1
(43) Pub. Date: Jun. 23, 2016

(54) ALIGNMENT CHECKING APPARATUS AND INTEGRATED CIRCUIT INCLUDING THE SAME

(71) Applicant: SK hynix Inc., Icheon-si Gyeonggi-do (KR)

(72) Inventor: Sang Mook OH, Icheon-si Gyeonggi-do (KR)

(21) Appl. No.: 14/663,684

(22) Filed: Mar. 20, 2015

(30) Foreign Application Priority Data
Dec. 22, 2014 (KR) 10-2014-0186141

(51) Int. Cl. G01R 1/067; G01R 31/28

(52) U.S. Cl. CPC G01R 1/06794; G01R 31/2884; G01R 31/2889

(57) ABSTRACT

An apparatus for checking alignment and an integrated circuit including the same are disclosed. The apparatus includes a center pad, an edge pad configured to surround the center pad and including an opening in at least one side, and a connection wiring configured to pass through the opening and electrically couple the center pad and an internal circuit.

### CROSS-REFERENCES TO RELATED APPLICATION

This application claims priority under 35 U.S.C. 119(a) to Korean application No. 10-2014-0186141 filed on Dec. 22, 2014, in the Korean intellectual property Office, which is incorporated by reference in its entirety.

### BACKGROUND

1. Technical Field

Embodiments of the inventive concept generally relate to an alignment checking apparatus and an integrated circuit including the same, and more particularly to an alignment checking apparatus for checking alignment of a probe pad and an integrated circuit including the same.

2. Related Art

A probe card is an apparatus used to test integrated circuits. The probe card includes a printed circuit board (e.g., a multi-layer board) in which circuit patterns for a test process of the integrated circuits are laid out, and a plurality of test needles which are used to make contact with probe pads of the integrated circuits. During the test process of the integrated circuits, test current generated by a tester may be provided to the integrated circuits through the circuit patterns and the needles. The test current may flow to parts of the integrated circuits through the probe pads of the integrated circuits to test electrical characteristics of the integrated circuits.

A wafer may have alignment checking apparatus thereon to check alignment between the test needles and the probe pads of the integrated circuits. The alignment checking apparatus may include a center pad and, an edge pad surrounding the center pad, and an insulating layer between the center pad and the edge pad. The probe card may detect to which portion of the alignment checking apparatus the test needle is connected so as to ensure accurate test results.

### SUMMARY

According to an embodiment, there is provided an apparatus for checking alignment. The apparatus may include a center pad, an edge pad configured to surround the center pad and including an opening in at least one side, and a connection wiring configured to pass through the opening and electrically couple the center pad and an internal circuit.

According to an embodiment, there is provided a semiconductor integrated circuit device. The semiconductor integrated circuit device may include an apparatus for checking alignment located in a scribe lane of a wafer. The apparatus may include a center pad coupled to a first internal circuit unit through a first connection wiring, and an edge pad configured to surround the center pad, coupled to a second internal circuit unit through a second connection writing, and including at least one opening. The first connection wiring may be configured to pass through the opening.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a schematic plan view illustrating a wafer according to an embodiment of the inventive concept;

FIG. 2 is an enlarged plan view of a portion “A” of FIG. 1;

FIG. 3 is a plan view illustrating an alignment checking apparatus according to an embodiment of the inventive concept;

FIG. 4 is a cross-sectional view illustrating the alignment checking apparatus taken along line IV-IV′ of FIG. 3;

FIG. 5 is a cross-sectional view illustrating the alignment checking apparatus taken along line V-V′ of FIG. 3;

FIG. 6 is a plan view illustrating an alignment checking apparatus according to an embodiment of the inventive concept;

FIG. 7 is an internal circuit diagram illustrating an electrostatic discharge (“ESD”) circuit unit according to an embodiment of the inventive concept;

FIG. 8 is a plan view illustrating an alignment checking apparatus according to an embodiment of the inventive concept;

FIG. 9 is a plan view illustrating an alignment checking apparatus according to an embodiment of the inventive concept; and

FIG. 10 is a plan view illustrating an alignment checking apparatus according to an embodiment of the inventive concept.

### DETAILED DESCRIPTION

Hereinafter, exemplary embodiments will be described in greater detail with reference to the accompanying drawings. Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

The inventive concept is described herein with reference to cross-section and/or plan illustrations that are schematic illustrations of idealized embodiments of the inventive concept. However, embodiments of the inventive concept should not be limited construed as limited to the inventive concept. Although a few embodiments of the inventive concept will be shown and described, it will be appreciated by those of ordinary skill in the art that changes may be made in these exemplary embodiments without departing from the principles and spirit of the inventive concept.

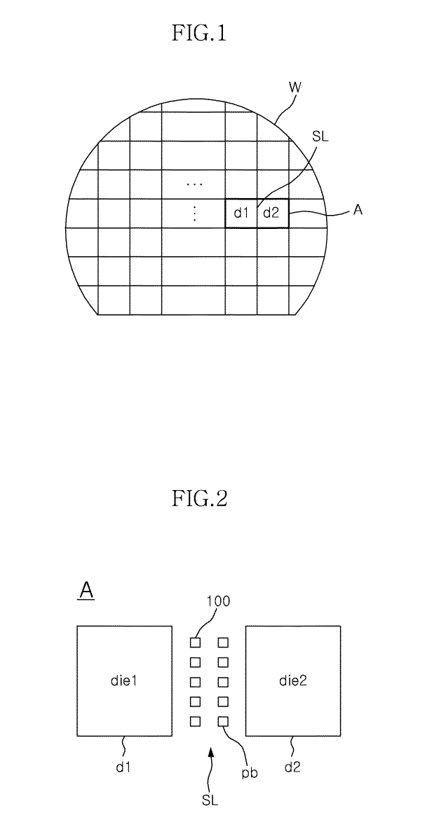

Referring to FIGS. 1 and 2, an alignment checking apparatus 100 in an embodiment may be located in a scribe lane SL of a wafer W in which general probe pads pb are formed. The scribe lane SL may be a line formed in between two adjacent dies d1 and d2 so that die sawing is performed on the scribe lane SL.

A plurality of test patterns and a plurality of probe pads pb may also be located on the scribe lane SL. The test patterns formed on the scribe lane SL may be removed in a subsequent die sawing process.

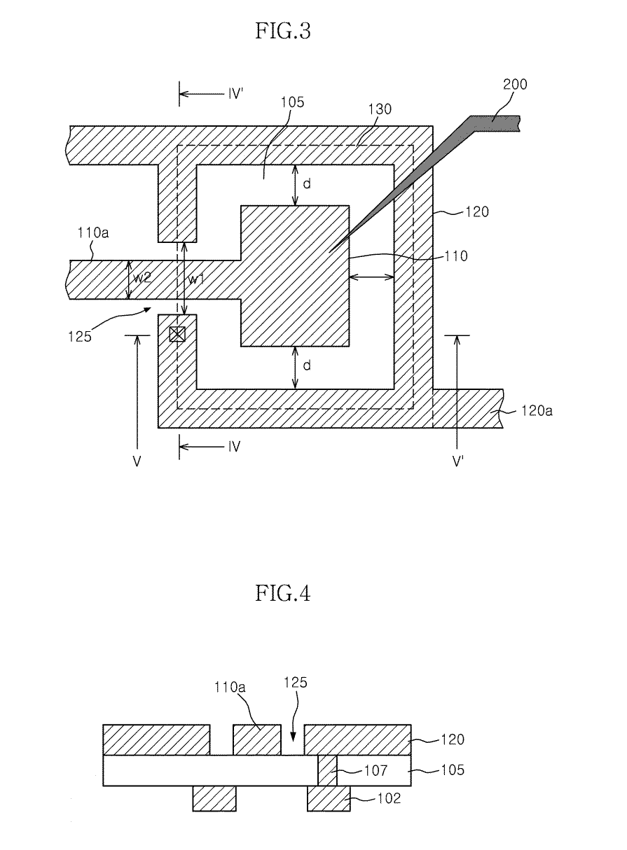

Referring to FIG. 3, the alignment checking apparatus 100 in an embodiment may include a center pad 110 and an edge pad 120.

The center pad 110 and the edge pad 120 may be formed such that the edge pad 120 surrounds the center pad 110. The edge pad 120, which surrounds the center pad 110, may have a predetermined distance d from the center pad 110. The edge pad 120 may include at least one opening 125. The opening 125 may be formed at a side of the edge pad 120. A first connection wiring 110a, which is connected to the center pad 110, may extend through the opening 125 to be electrically coupled to another internal circuit located outside the alignment checking apparatus 100 and receive a certain voltage. For example, the opening 125 may be formed at a side of the edge pad 120 facing the other internal circuit to minimize a length of the first connection wiring 110a.

The opening 125 may have a width w1 greater than a width w2 of the first connection wiring 110a. The first connection wiring 110a may extend to the outside of the alignment checking apparatus 100 without contact with the edge pad 120. An interlayer insulating layer 105 may be located between the edge pad 120 and the center pad 110 when viewed in a plan view.

When the alignment checking apparatus 100 is electrically coupled to a probe needle 200, a tester may detect which portion of the alignment checking apparatus 100 the probe needle 200 is in contact with by detecting current flowing through the probe needle 200, thereby checking an alignment error.

A second connection wiring 120a may also be formed to couple the edge pad 120 and a voltage transfer pad (not shown). The reference numeral 130 denotes a boundary of a passivation layer, which may be used to selectively open the alignment checking apparatus 100.

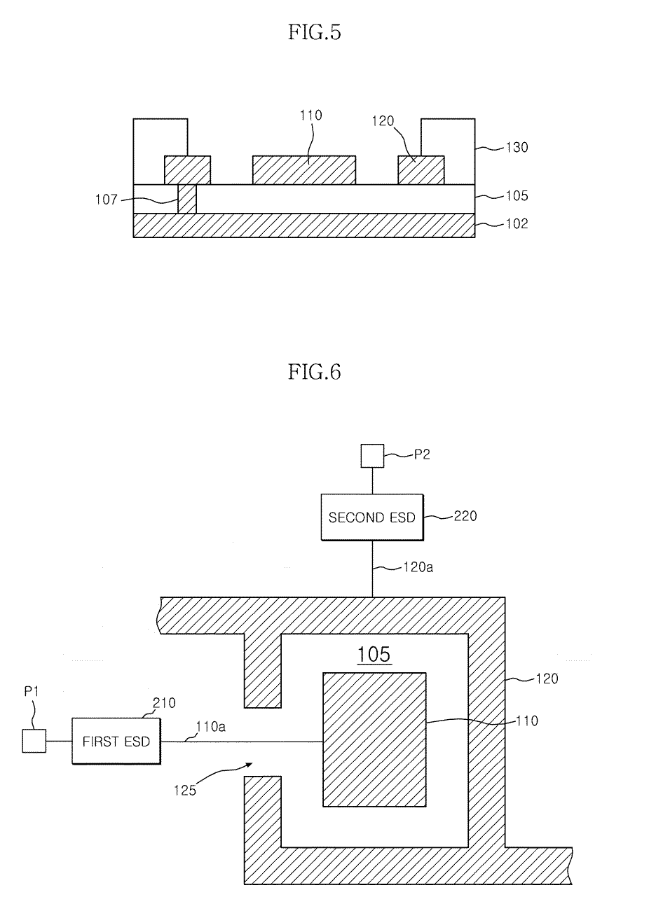

The center pad 110 and the edge pad 120 may be electrically coupled to internal circuits to which certain voltages are provided. For example, the center pad 110 and the edge pad 120 may be electrically coupled voltage transfer pads (not shown). The same voltage may be applied to a voltage transfer pad coupled to the center pad 110 and a voltage transfer pad coupled to the edge pad 120. Further, voltages having different voltage levels may be applied to the voltage transfer pad coupled to the center pad 110 and the voltage transfer pad coupled to the edge pad 120 as illustrated in FIG. 6.

In case where an edge pad has a closed-loop shape, if a center pad surrounded with the edge pad, a connection wiring, and a voltage transfer pad are on the same plane, it is difficult to couple those things to each other. Thus, the connection wiring coupled to the center pad must be bypassed to a different layer (e.g., a lower layer) to be coupled to the voltage transfer pad, and therefore additional processes such as a contact formation process and an etching process are necessary to couple the center pad, the connection wiring, and the voltage transfer pad to each other. If the connection wiring is bypassed through the lower layer, a length of the connection wiring is increased.

In an embodiment, the opening 125 is provided in a certain portion of the edge pad 120, which is formed in an open-loop shape. The center pad 120 may be electrically coupled to the voltage transfer pad on the same plane without a bypass to a lower layer. Therefore, the alignment checking apparatus 100 may be formed without the etching process and contact formation process, which may cause a contact error.

FIG. 4 is a cross-sectional view illustrating the alignment checking apparatus taken along line IV-IV′ of FIG. 3, and FIG. 5 is a cross-sectional view illustrating the alignment checking apparatus taken along line V-V′ of FIG. 3.

Referring to FIGS. 4 and 5, the opening 125 is provided in the edge pad 120. The connection wiring 110a of the center pad 110 is located in the opening 125. The connection wiring 110a is formed on the same plane as the edge pad 120, for example, on the interlayer insulating layer 105 without use of the lower layer below the edge pad 120.

In an embodiment, the edge pad 120 may be coupled to a lower wiring layer 102 through a lower contact 107.

Referring to FIG. 6, a first ESD circuit unit 210 may be coupled between a center pad 110 and a first voltage transfer pad P1, and a second ESD circuit unit 220 may be coupled between an edge pad 120 and a second voltage transfer pad P2.

The first and second ESD circuit units 210 and 220 may be provided to discharge electrostatic which may be generated when the probe needle 200 of FIG. 3 is in contact with the center pad 110 or the edge pad 120.

In an embodiment, the edge pad 120 may include the opening 125, and the first connection wiring 110a electrically connecting the first ESD circuit unit 210 and the center pad 110 may extend through the opening 125.

The edge pad 120 may be coupled to the second ESD circuit unit 220 through the second connection wiring 120a.

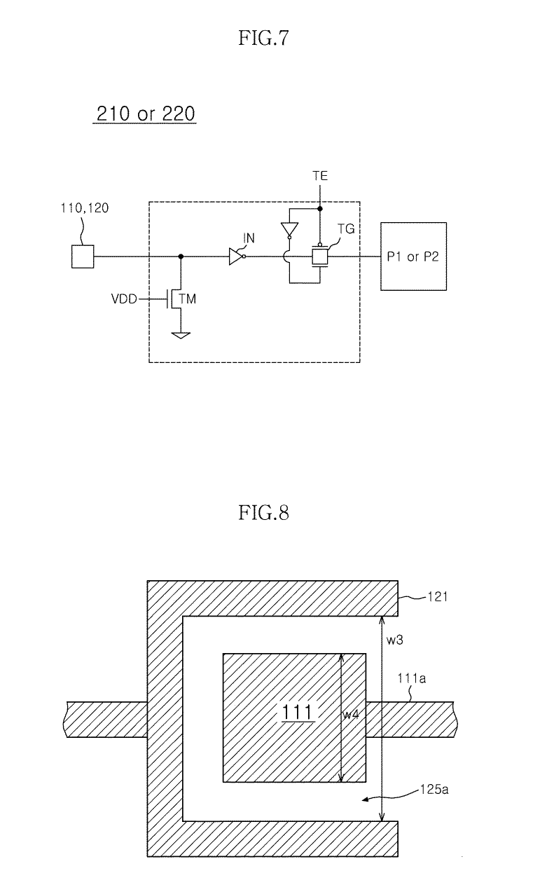

FIG. 7 is an internal circuit diagram illustrating the first or second ESD circuit unit 210 or 220 of FIG. 6.

Referring to FIG. 7, the first or second ESD circuit unit 210 or 220 may include a MOS transistor TM, an inverter IN, and a transfer gate TG.

The MOS transistor TM may include a gate to which an operation voltage VDD is applied, a drain coupled to the center pad 110 or the edge pad 120, and a source coupled to a ground terminal.

The inverter IN may be coupled to the drain of the MOS transistor, and the center pad 110 or the edge pad 120, and output a logic level opposite to the center pad 110 or the edge pad 120 when the voltage of the center pad 110 or the edge pad 120 is applied thereto.

The transfer gate TG may selectively provide an output signal of the inverter IN to the first or second voltage transfer pad P1 or P2 in response to a probe test signal TE.

When electrostatic charge is generated at the center pad 110 and/or the edge pad 120 during the probe test, the electrostatic charge may be discharged through the MOS transistor TM which is always turned on, and therefore the first and the second voltage transfer pads P1 and P2 may be protected from the electrostatic charge.

Various types of ESD circuits other than the ESD circuit illustrated in FIG. 7 may be used as the first and second ESD circuit units 210 and 220 of the embodiment.

The center pad and the edge pad may be implemented in various shapes.

For example, as illustrated in FIG. 8, an edge pad 121 may be formed in a concave form, and a center pad 111 may be formed in a convex form, when viewed from above. The edge pad 121 may have an opening 125a, and the opening 125a may have a width w3 greater than a width w4 of the center pad 111. The center pad 111 may be surrounded with the edge pad 121 except for the opening 125a. The center pad 111 may be connected to the outside of the edge pad 121 through a connection wiring 111a without a bypass to a lower layer.

Referring to FIG. 9, an edge pad 122 may include a pair of openings 125a and 125b facing to each other. First and second connection wirings 112a and 112b coupled to a center pad 112 may extend through the pair of openings 125a and 125b.

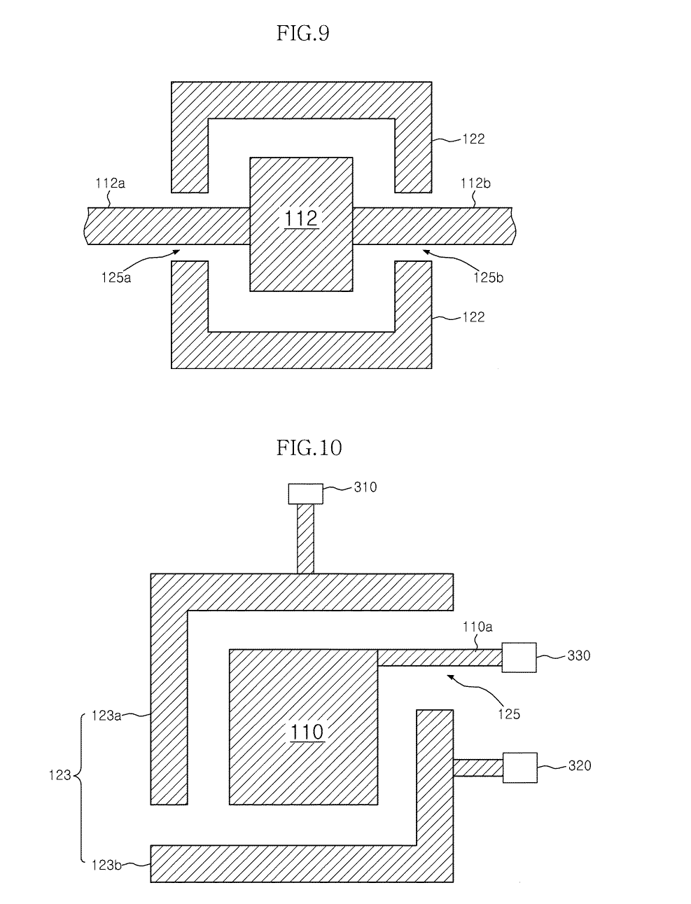

Referring to FIG. 10, an edge pad 123 surrounding a center pad 110 may have at last two openings 125. The edge pad 123 may be divided into unit edge pads such as a first unit edge pad 123a and a second unit edge pad 123b. The first unit edge pad 123a may be electrically coupled to a first voltage providing unit 310, and the second unit edge pad 123b may be electrically coupled to a second voltage providing unit 320. For example, each of the first and second unit edge pads 123a and 123b may have “L” shape. The center pad 110 may be electrically coupled to a third voltage providing unit 330 through a first connection wiring 110a which passes through any one among a plurality of openings 125.

Voltage levels provided from the first voltage providing unit 310, the second voltage providing unit 320, and the third voltage providing unit 330 may be different from each other. The first to third voltage providing unit 310 to 330 may include voltage regulators.

Therefore, voltage level may vary according to which pad comes into contact with the probe needle, and thus a tester may figure out where the probe needle is located.

According to an embodiment of the inventive concept, the alignment checking apparatus for probe test may include an opening, which is provided for a connection wiring of a center pad, in an edge pad region. The center pad may be coupled to the outside of the edge pad region without a bypass to a lower layer. Therefore, the alignment checking apparatus may be formed without an etching process and a contact formation process for the bypass to a lower layer, which may cause an electrical defect.

The above embodiment of the present invention is illustrative and not limitative. Various alternatives and equivalents are possible. The invention is not limited by the embodiment described herein. Nor is the invention limited to any specific type of integrated circuit or semiconductor device. Other additions, subtractions, or modifications are obvious in view of the present disclosure and are intended to fall within the scope of the appended claims.

What is claimed is:

1. An alignment checking apparatus comprising:
a center pad;
an edge pad configured to surround the center pad and including an opening in at least one side; and
a connection wiring configured to pass through the opening and electrically couple the center pad and an internal circuit.

2. The alignment checking apparatus of claim 1, wherein the center pad is electrically coupled to a first voltage transfer pad, and the edge pad is electrically coupled to a second voltage transfer pad.

3. The alignment checking apparatus of claim 2, wherein the same voltage is applied to the first and second voltage transfer pads.

4. The alignment checking apparatus of claim 2, wherein voltages having different voltage levels are applied to the first and second voltage transfer pads.

5. The alignment checking apparatus of claim 2, wherein the center pad is coupled to a first ESD circuit unit, which is coupled to the first voltage transfer pad through the connection wiring, and the edge pad is coupled to a second ESD circuit unit, which is coupled to the second voltage transfer pad through an additional connection wiring.

6. The alignment checking apparatus of claim 1, wherein a width of the opening is greater than that of the connection wiring.

7. The alignment checking apparatus of claim 1, wherein a width of the opening is greater than that of the center pad, and the center pad and the connection wiring are surrounded with the edge pad except for the opening.

8. The alignment checking apparatus of claim 1, wherein the edge pad includes a plurality of openings, and is divided into a plurality of unit edge pads, and voltages having different voltage levels are provided to the unit edge pads and the center pad.

9. The alignment checking apparatus of claim 1, further comprising an interlayer insulating layer between the center pad and the edge pad.

10. The alignment checking apparatus of claim 9, wherein the center pad, the edge pad, and the connection wiring are located on an upper surface of the interlayer insulating layer.

11. An integrated circuit comprising:
an apparatus for checking alignment located in a scribe lane of a wafer, the apparatus including a center pad coupled to a first internal circuit unit through a first connection wiring, and an edge pad configured to surround the center pad, coupled to a second internal circuit unit through a second connection writing, and including at least one opening,
wherein the first connection wiring is configured to extend through the opening.

12. The integrated circuit of claim 11, wherein the first and second internal circuit units are voltage transfer pads to which certain voltages are applied.

13. The integrated circuit of claim 11, wherein the first and second internal circuit units are configured to provide the same voltage to the center pad and the edge pad.

14. The integrated circuit of claim 11, wherein the first and second internal circuit units are configured to provide voltages having different voltage levels to the center pad and the edge pad.

15. The integrated circuit of claim 12, wherein the first and second internal circuit units includes ESD circuit units coupled to the voltage transfer pads.

16. The integrated circuit of claim 11, wherein the opening is configured to have a width greater than that of the first connection wiring.

17. The integrated circuit of claim 11, wherein a width of the opening is greater than that of the center pad, and the center pad and the first connection wiring are surrounded with the edge pad except for the opening.

18. The integrated circuit of claim 11, wherein the edge pad includes a plurality of openings, and is divided into a plurality of unit edge pads, and
the edge pad is configured to provide voltages having different voltage levels to the unit edge pads and the center pad.

19. The integrated circuit of claim 11, further comprising an interlayer insulating layer,
wherein the center pad, the edge pad, and the first and second connection wirings are located on an upper surface of the interlayer insulating layer.
